(19) United States
(12) Patent Application Publication
(10) Pub. No.: US 2026/0324132 A1
(43) Pub. Date: Oct. 15, 2026

(54) FLIP-CHIP LIGHT EMITTING DIODE AND MANUFACTURING METHOD THEREOF

(71) Applicant: Taiwan-Asia Semiconductor Corporation, Hsinchu City (TW)

(72) Inventors: Po-Jen Hsieh, Hsinchu City (TW); Ming-Chieh Lin, Hsinchu City (TW)

(21) Appl. No.: 19/644,670

(22) Filed: Apr. 10, 2026

(30) Foreign Application Priority Data
Apr. 14, 2025 (TW) 114114076

(51) Int. Cl. H10H 20/01

(52) U.S. Cl. CPC H10H 20/017; H10H 20/018

(57) ABSTRACT

The invention provides a manufacturing method of a flip-chip light emitting diode, which includes following steps: providing a first substrate; performing an epitaxy process on the first substrate to form a semiconductor structure, wherein the semiconductor structure includes a current conducting layer on which a bonding side is formed and a first electrode projection area and a second electrode projection area are defined; performing an etching process to form at least one groove on the bonding side; performing a filling process to fill a transparent material into the at least one groove for changing a current conducting path on the bonding side; performing a bonding process to bond the second substrate to the bonding side; and removing the first substrate and forming a first electrode and a second electrode on a side, adjacent to the first substrate, of the semiconductor structure. Wherein a position of the first electrode corresponds to the first electrode projection area and a position of the second electrode corresponds to the second electrode projection area.

### CROSS REFERENCE TO RELATED APPLICATION

This application claims the benefit of Taiwan Patent Application Serial No. 114114076 filed on Apr. 14, 2025. The entirety of each Application is incorporated herein by reference.

### BACKGROUND OF THE INVENTION

### 1. Field of the Invention

The present invention relates to a flip-chip light emitting diode and a manufacturing method thereof, and more particularly, to a flip-chip light emitting diode with an improved current density and an increased light emitting area and a manufacturing method thereof.

### 2. Description of Related Art

As shown in FIG. 1, for a conventional flip-chip LED 200, a P-type metal electrode 210 and an N-type metal electrode 220 are generally arranged below a semiconductor light emitting structure 230 and a current conducting layer 240 (i.e., near the bottom of the drawing), and a transparent substrate 250 covers on top of a bonding side 240a of the current conducting layer 240. Thus, after the P-type metal electrode 210 and the N-type metal electrode 220 are conducted, electric current is able to flow through the current conducting layer 240 and drive the semiconductor light emitting structure 230 to emit light which passes through the transparent substrate 250 at last, so as to achieve a light emitting effect.

FIG. 2 is a top view from the top of FIG. 1 toward the transparent substrate 250 and the bonding side 240a of the current conducting layer 240. Wherein a left dotted rectangular frame corresponds to a projection area 241 of the P-type metal electrode 210 shown in FIG. 1, and a right dotted rectangular frame corresponds to a projection area 242 of the N-type metal electrode 220 shown in FIG. 1. As illustrated in FIG. 1 and FIG. 2, when the P-type metal electrode 210 and the N-type metal electrode 220 are conducted, current conducting paths are almost conducted in a straight line manner between the projection area 241 of the P-type metal electrode 210 and the projection area 242 of the N-type metal electrode 220, thus presenting a diffusion of an oblong area light source as shown in FIG. 2. Even if a shape design of the entire light-emitting surface is changed or an area of the light-emitting surface is increased, the current will still be conducted along those shortest paths and still form the oblong area light source, so that light-emitting efficiency is unable to be improved. Furthermore, since the current is concentrated and conducted in the straight line manner between the projection area 241 of the P-type metal electrode 210 and the projection area 242 of the N-type metal electrode 220, a current density will be too high, which may cause problems such as overheating, poor electrostatic discharging or excessive electric leaking.

In light of this, it is really worthy of research and development to design a flip-chip light emitting diode and a manufacturing method thereof for solving those above-mentioned problems.

### SUMMARY OF THE INVENTION

An objective of the present invention is to provide a manufacturing method of a flip-chip light emitting diode with an improved current density and an increased light emitting area.

To achieve the above objective, the manufacturing method of the flip-chip light emitting diode includes following steps: providing a first substrate; performing an epitaxy process on the first substrate to form a semiconductor structure, wherein the semiconductor structure includes a first semiconductor epitaxy layer, a light-emitting layer, a second semiconductor epitaxy layer and a current conducting layer, in sequence from a position adjacent to the first substrate, and wherein a bonding side is formed for the current conducting layer and a first electrode projection area and a second electrode projection area are defined thereon; performing an etching process to form at least one groove on the bonding side, wherein each groove extends from a side near the first electrode projection area to a side near the second electrode projection area; performing a filling process to fill a transparent material into the at least one groove for changing a current conducting path on the bonding side; performing a bonding process to bond the second substrate to the bonding side; and removing the first substrate and forming a first electrode and a second electrode on a side of the semiconductor structure adjacent to the first substrate, wherein a position of the first electrode corresponds to the first electrode projection area and the first electrode is electrically connected to the first semiconductor epitaxy layer, and wherein a position of the second electrode corresponds to the second electrode projection area and the second electrode is electrically connected to the current conducting layer.

In one embodiment of the present invention, the at least one groove is located somewhere other than a position on a shortest connection path between the first electrode projection area and the second electrode projection area

In one embodiment of the present invention, an impedance value of the transparent material is lower than an impedance value of the current conducting layer.

In one embodiment of the present invention, the impedance value of the current conducting layer is 10 to 1000 times of the impedance value of the transparent material.

In one embodiment of the present invention, the transparent material is selected from one of following material groups of indium zinc oxide, aluminum zinc oxide and indium tin oxide.

In one embodiment of the present invention, the at least one groove is located at a position on a shortest connection path between the first electrode projection area and the second electrode projection area.

In one embodiment of the present invention, an impedance value of the transparent material is higher than an impedance value of the current conducting layer.

In one embodiment of the present invention, the impedance value of the transparent material is 10 to 1000 times of the impedance value of the current conducting layer.

In one embodiment of the present invention, the transparent material is selected from one of following material groups of silicon oxide, silicon nitride and magnesium fluoride.

In one embodiment of the present invention, each at least one groove is a straight-line groove, a rectangular groove, a circular groove, an elliptical groove, a curved groove, a fence-like groove, a tree-like groove or a radial groove.

The present invention further provides a flip-chip light emitting diode. The flip-chip light emitting diode is manufactured according to the aforementioned manufacturing method of the flip-chip light emitting diode.

With the above design, the at least one groove is formed on the bonding side of the current conducting layer by performing the etching process and is filled with the transparent material by performing the filling process for the manufacturing method of the flip-chip light emitting diode of the present invention, so as to change current conducting paths on the bonding side of the current conducting layer, thereby preventing an excessive current density and increasing a light-emitting area and brightness of the flip-chip light emitting diode. In addition, the flip-chip light emitting diode manufactured by the above manufacturing method of the present invention exhibits improved heat dissipation performance and enhanced electrostatic discharging effect.

### BRIEF DESCRIPTION OF THE DRAWINGS

FIG. 1 is a schematic view of a structure of a conventional flip-chip light emitting diode;

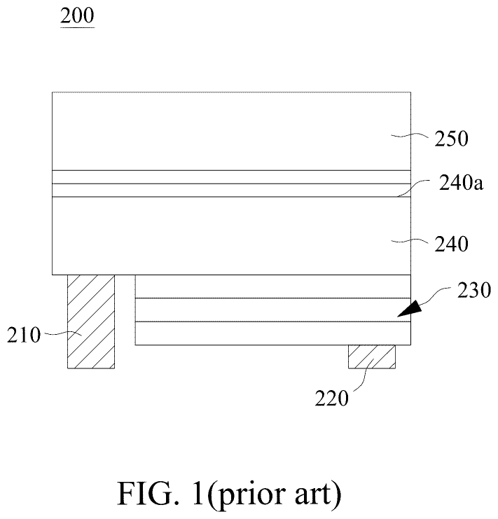

FIG. 2 is a schematic view of the conventional flip-chip light emitting diode as shown in FIG. 1 in a light-emitting state;

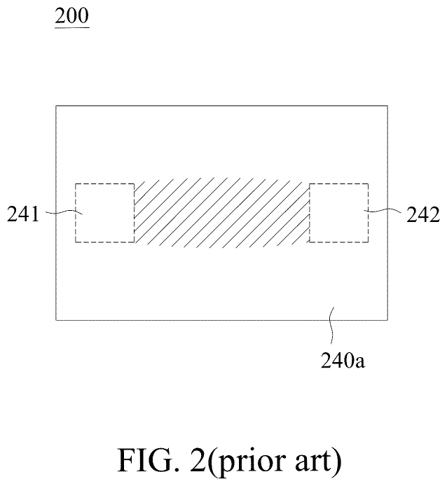

FIG. 3 is a flowchart of a manufacturing method of a flip-chip light emitting diode according to the present invention;

FIG. 4 is a schematic view of structures corresponding to steps of the manufacturing method of the flip-chip light emitting diode according to the present invention;

FIG. 5 is a schematic view of current conducting paths formed on a bonding side of a current conducting layer of a first embodiment according to the present invention;

FIG. 6 is a schematic view of current conducting paths formed on a bonding side of a current conducting layer of a second embodiment according to the present invention;

FIG. 7 is a schematic view of current conducting paths formed on a bonding side of a current conducting layer of a third embodiment according to the present invention;

FIG. 8 is a schematic view of a flip-chip light emitting diode produced by the manufacturing method of the flip-chip light emitting diode according to the present invention.

### DETAILED DESCRIPTION OF THE PREFERRED EMBODIMENT

Since various examples and embodiments in the present invention are only illustrative and non-restrictive, a person skilled in the art can easily conceive other examples and embodiments without contravening the scope of the present invention, after reading this specification, and can make the features and advantages of these embodiments more evident based on the following detailed description and claims.

Herein, the description of unit, element and component in the present invention uses “one”, “a”, or “an”. This is for convenience and for offering general meaning of the category of the present invention. Therefore, the description should be understood as including “one”, “at least one”, and singular and plural forms at the same time unless the context clearly indicates otherwise.

Herein, the description of the terms “first” or “second” and similar ordinal numbers are mainly used to distinguish or refer to the same or similar elements or structures and do not necessarily imply that such components or structures are spatially or temporally distinct order. It should be understood that ordinal numbers, in certain situations or configurations, may be used interchangeably without affecting the implementation of the present invention.

Herein, the description of “comprise”, “have” or other similar semantics have the non-exclusive meaning. For example, components or structures with a plurality of elements are not only limited to those disclosed in this specification, but also include generally inherent elements, which are not explicitly listed here for the components or the structures.

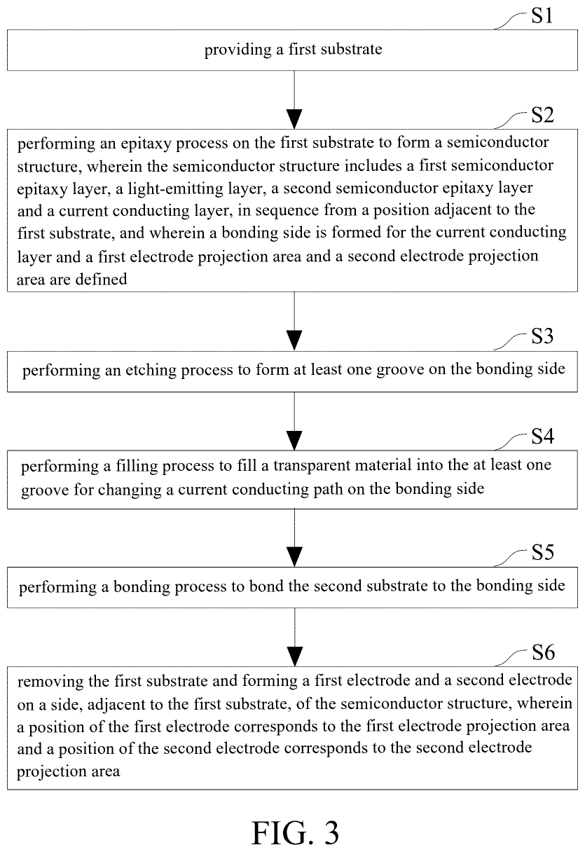

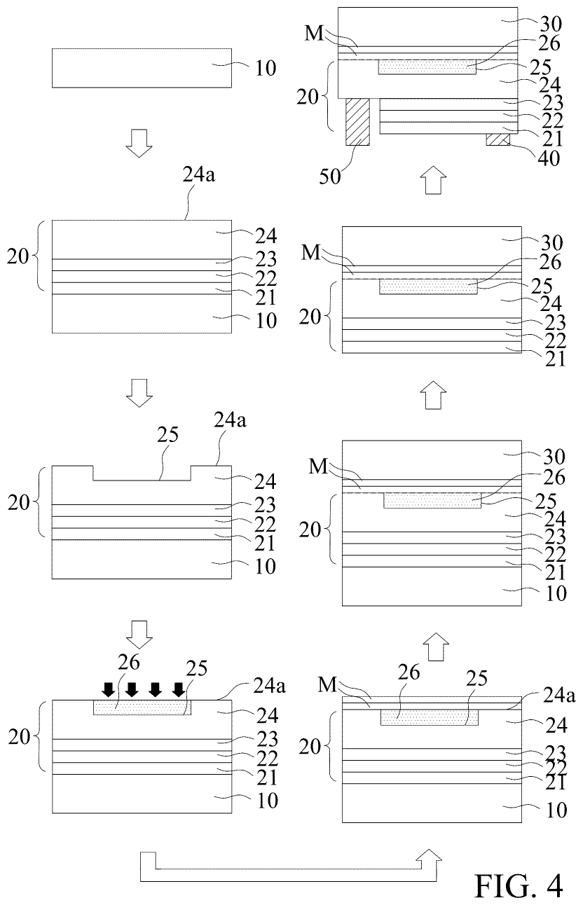

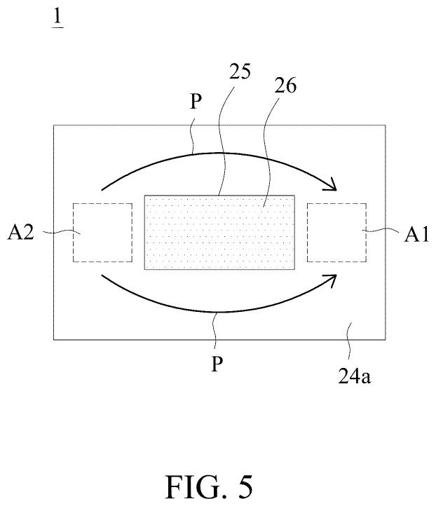

Please refer to FIG. 3, FIG. 4 and FIG. 5 together. Wherein FIG. 3 is a flowchart of a manufacturing method of a flip-chip light emitting diode according to the present invention, FIG. 4 is a schematic view of structures corresponding to steps of the manufacturing method of the flip-chip light emitting diode according to the present invention and FIG. 5 is a schematic view of current conducting paths formed on a bonding side 24a of a current conducting layer 24 of a first embodiment according to the present invention. As shown in FIG. 3 to FIG. 5, the manufacturing method of the flip-chip light emitting diode of the present invention comprises following steps.

Step S1: providing a first substrate 10.

First, the present invention provides the first substrate 10 as a temporary substrate of a flip-chip light emitting diode 1 of the present invention, for supporting other components of the flip-chip light emitting diode 1. The first substrate 10 is a plate structure, and in one embodiment of the present invention, the first substrate 10 is a gallium arsenide (GaAs) substrate. But the present invention is not limited thereto, other semiconductor materials or common substrate materials can be applied for the first substrate 10.

Step S2: performing an epitaxy process on the first substrate 10 to form a semiconductor structure 20, wherein the semiconductor structure 20 includes a first semiconductor epitaxy layer 21, a light-emitting layer 22, a second semiconductor epitaxy layer 23 and a current conducting layer 24, in sequence from a position adjacent to the first substrate 10, and wherein a bonding side 24a forms for the current conducting layer 24 and a first electrode projection area A1 and a second electrode projection area A2 are defined thereon.

After the first substrate 10 is provided in Step S1, the epitaxy process is performed for the present invention, to form the semiconductor structure 20 on the first substrate 10. Through the epitaxy process, the first semiconductor epitaxy layer 21, the second semiconductor epitaxy layer 23 and the current conducting layer 24 are sequentially stacked from where the semiconductor structure 20 abuts the first substrate 10, and the light-emitting layer 22 is formed at an interface between the first semiconductor epitaxy layer 21 and the second semiconductor epitaxy layer 23, so that the semiconductor structure 20 primarily provides a light-emitting effect as being conducted. In one embodiment of the present invention, the first semiconductor epitaxy layer 21 is made of N-type semiconductor materials, such as N-type aluminum gallium indium phosphide (N—AlGaInP). The light-emitting layer 22 is a multiple-quantum well (MQW) layer. The second semiconductor epitaxy layer 23 is made of P-type semiconductor materials, such as P-type aluminum gallium indium phosphide (P—AlGaInP). The current conducting layer 24 is made of P-type gallium phosphide (P—GaP) (e.g., doped with magnesium (Mg)). However, the materials of the layers of the semiconductor structure 20 are not limited to the aforementioned materials.

Since the current conducting layer 24 is stacked on top of the semiconductor structure 20, the current conducting layer 24 forms an exposed bonding side 24a having a large area. In subsequent manufacturing processes, a first electrode 40 and a second electrode 50 are necessarily to be formed on a surface of one side of the semiconductor structure 20 adjacent to the first substrate 10. By projecting an area, where the first electrode 40 is to be pre-disposed, onto the bonding side 24a of the current conducting layer 24 along a straight line direction perpendicular to the aforementioned surface of the side, the first electrode projection area A1 is then formed. In addition, by projecting an area, where the second electrode 50 is to be pre-disposed, onto the bonding side 24a of the current conducting layer 24 along a straight line direction perpendicular to the aforementioned surface of the side, the second electrode projection area A2 is then formed. In one embodiment of the present invention, cross-sections, parallel the bonding side 24a, of the first electrode 40 and of the second electrode 50 are rectangular, so that the first electrode projection area A1 and the second electrode projection area A2 are also rectangular areas, but not limited thereto for the present invention.

Step S3: performing an etching process to form at least one groove 25 on the bonding side 24a.

As the semiconductor structure 20 is formed in Step S2, the etching process is performed on the bonding side 24a of the current conducting layer 24 for the present invention. The etching process is mainly for forming the at least one groove 25 on the bonding side 24a of the current conducting layer 24. In the present invention, a current conducting path of the current conducting layer 24 can be planned before performing the etching process, and the at least one groove 25 is formed at a corresponding position according to the planned current conducting path. Each groove 25 extends from a side near the first electrode projection area A1 to a side near the second electrode projection area A2, and a depth of each groove 25 does not exceed a thickness of the current conducting layer 24.

Depending on design requirements of different current conducting paths, the number and the position of the at least one groove 25 may vary. For example, the at least one groove 25 may be only one single groove 25 or a plurality of grooves 25. In the present invention, the at least one groove 25 may be planned to locate at a position other than a position on one shortest connection path between the first electrode projection area A1 and the second electrode projection area A2 (e.g., on both sides outside the aforementioned shortest connection path), or one of the at least one groove 25 may be planned to locate at a position on the shortest connection path between the first electrode projection area A1 and the second electrode projection area A2 (in this case, the remaining grooves 25 may be planned to located at positions other than the positions on the shortest connection path between the first electrode projection area A1 and the second electrode projection area A2).

A length, a width and a shape of each groove 25 can be varied depending on different design requirements. In one embodiment of the present invention, each groove 25 is a straight-line groove, a rectangular groove, a circular groove, an elliptical groove, a curved groove, a fence-like groove, a tree-like groove or a radial groove.

Step S4: performing a filling process to fill a transparent material 26 into the at least one groove 25 for changing a current conducting path on the bonding side 24a.

After the etching process is performed in the aforementioned Step S3, the filling process is then performed on the bonding side 24a of the current conducting layer 24 for the present invention. The filling process mainly adopts the transparent material 26 to fill the at least one groove 25, so that each transparent material 26 filled in the corresponding groove 25 can be regarded as a three-dimensional current conducting block or current separating block after being formed. Herein, an impedance value of the transparent material 26 is different from an impedance value of the current conducting layer 24. According to functions of current conducting or of current separating to be provided, the aforementioned transparent material 26 is selected from transparent materials with different impedance values.

For example, if the transparent material 26 is planned to provide the current conducting function, the impedance value of the transparent material 26 must be lower than the impedance value of the current conducting layer 24. In one embodiment of the present invention, the transparent material 26 is selected from one of following material groups of indium zinc oxide (IZO), aluminum zinc oxide (AZO) and indium tin oxide (ITO). In one embodiment of the present invention, the impedance value of the current conducting layer 24 is 10 to 1000 times of the impedance value of the transparent material 26, but the present invention is not limited thereto.

And for example, if the transparent material 26 is planned to provide the current separating function, the impedance value of the transparent material 26 must be higher than the impedance value of the current conducting layer 24. In one embodiment of the present invention, the transparent material 26 is selected from one of following material groups of silicon oxide (SiOₓ), silicon nitride (SiNₓ) and magnesium fluoride (MgF₂). In one embodiment of the present invention, the impedance value of the transparent material 26 is 10 to 1000 times of the impedance value of the current conducting layer 24, but the present invention is not limited thereto.

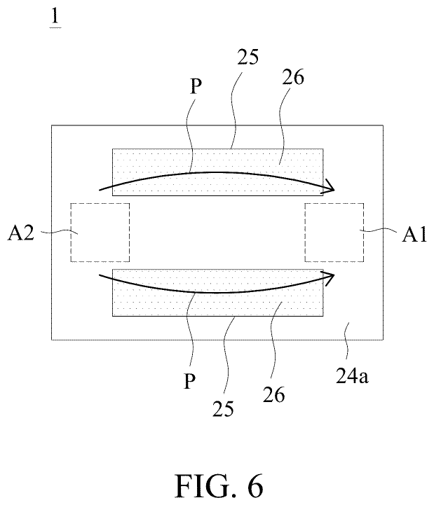

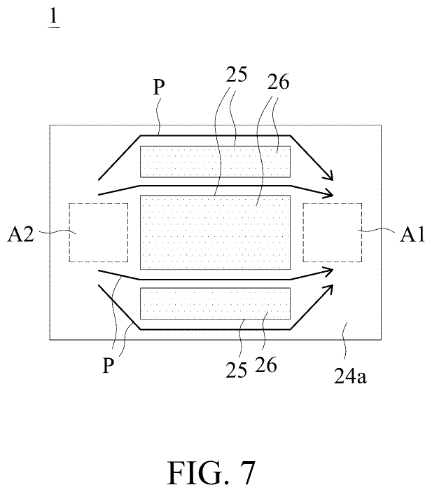

Please refer to FIG. 5 to FIG. 7 simultaneously, wherein FIG. 6 is a schematic view of current conducting paths P formed on a bonding side 24a of a current conducting layer 24 of a second embodiment according to the present invention, and FIG. 7 is a schematic view of current conducting paths P formed on a bonding side 24a of a current conducting layer 24 of a third embodiment according to the present invention. In the following embodiments, the grooves 25 are described as rectangular grooves, but the present invention is not limited thereto. As shown in FIG. 5, in this embodiment, one single groove 25 is formed on the bonding side 24a of the current conducting layer 24. This groove 25 is located at a position on the shortest connection path between the first electrode projection area A1 and the second electrode projection area A2. This groove 25 is filled with a transparent material 26 having a higher impedance value than that of the current conducting layer 24, so that the transparent material 26 serves as the current separating block after being formed.

In conventional flip-chip light emitting diode designs, a straight-line connection path between the first electrode projection area and the second electrode projection area is short and has a low impedance value, causing electric current to flow along this straight-line connection path. In contrast, in this embodiment, due to an impedance value differentiation caused by disposing of the current separating block, electric current primarily bypasses the transparent material 26 and flows along both sides outside the transparent material 26, forming a plurality of current conducting paths P as shown in FIG. 5. This induces an effect of current dispersing, thereby increasing the current flow area and thereby increasing the light-emitting area and brightness of the flip-chip light emitting diode.

As shown in FIG. 6, in this embodiment, two grooves 25 are formed on the bonding side 24a of the current conducting layer 24. These grooves 25 are respectively located on two sides outside the shortest connection path between the first electrode projection area A1 and the second electrode projection area A2. These grooves 25 are filled with a transparent material 26 having a lower impedance value than that of the current conducting layer 24, so that the transparent material 26 serves as the current conducting block after being formed.

In this embodiment, due to an impedance value differentiation caused by disposing of the aforementioned current conducting blocks, electric current mainly bypasses the shortest connection path between the first electrode projection area A1 and the second electrode projection area A2 and is conducted along both sides outside the transparent material 26, thereby forming a plurality of current conducting paths P as shown in FIG. 6. This induces an effect of current dispersing, thereby increasing the current flow area and thereby increasing the light-emitting area and brightness of the flip-chip light emitting diode.

As shown in FIG. 7, in this embodiment, three grooves 25 are formed on the bonding side 24a of the current conducting layer 24, and those grooves 25 are respectively located on the shortest connection path of the first electrode projection area A1 and the second electrode projection area A2 and on both sides outside the shortest connection path. The grooves 25 are filled with a transparent material 26 having a higher impedance value than that of the current conducting layer 24, so that the transparent material 26 serves as the current separating block after being formed.

In this embodiment, due to an impedance value differentiation caused by the disposing of the aforementioned current separating blocks, the electric current mainly bypasses the aforementioned transparent material 26 and is conducted along paths where the transparent material 26 does not exist, thereby forming a plurality of current conducting paths P as shown in FIG. 7 for resulting in an effect of current dispersing, and thus the current flow area is enhanced to increase the light-emitting area and brightness of the flip-chip light emitting diode.

Accordingly, in the present invention, a plurality of current conducting paths P are planned to locate at those positions which is less likely for the electric current to pass through in the conventional flip-chip light-emitting diodes, thereby improving the problem of the conduction current crowding of the conventional flip-chip light-emitting diodes and increasing the light-emitting area and brightness.

Furthermore, each current conducting path P is designed to have an impedance value within a default range. That is, in the present invention, the impedance value of any current conducting path P is kept similar to the impedance value of another current conducting path P, to be arranged within the same range of the impedance value. This ensures that the impedance values of any two current conducting paths P do not differ significantly, allowing electric current to be conducted through these current conducting paths P for achieving a better effect of current dispersing and for preventing current crowding in any one current conducting path P. Moreover, through etching and filling processes for disposing of the grooves 25 and the transparent materials 26, the current conducting paths P are formed for the present invention, so that each current conducting path P has the impedance value within the default range (for example, the default range is the same as or similar to the impedance value of the aforementioned shortest path).

Step S5: performing a bonding process to bond the second substrate 30 to the bonding side 24a.

After the filling process is performed in Step S4, a bonding process on the semiconductor structure 20 is performed for the present invention, making the second substrate 30 to cover and bond to the bonding side 24a of the current conducting layer 24, so that bonding between the second substrate 30 and the semiconductor structure 20 is completed. In one embodiment of the present invention, the second substrate 30 is a sapphire substrate. However, the present invention is not limited thereto, and the second substrate 30 may also be made of other

### Transparent Materials.

To facilitate bonding the second substrate 30 smoothly to the bonding side 24a of the current conducting layer 24, in one embodiment of the present invention, at least one bonding material M may be coated on the bonding side 24a before performing the bonding process. The at least one bonding material M is a viscously colloid-like material. For example, the at least one bonding material M may be a laminated coating of silicon dioxide (SiO₂) and aluminum oxide (Al₂O₃), but the present invention is not limited thereto.

Step S6: removing the first substrate 10 and forming a first electrode 40 and a second electrode 50 on a side, adjacent to the first substrate 10, of the semiconductor structure 20, wherein a position of the first electrode 40 corresponds to the first electrode projection area A1 and the first electrode 40 is electrically connected to the first semiconductor epitaxy layer 21, and a position of the second electrode 50 corresponds to the second electrode projection area A2 and the second electrode 50 is electrically connected to the current conducting layer 24.

After the bonding process is performed in aforementioned Step S5, the first substrate 10 adjacent to the semiconductor structure 20 is removed, and then etching and electrode forming processes are performed on one side of the semiconductor structure 20 originally adjacent to the first substrate 10, to form the first electrode 40 and the second electrode 50 on the semiconductor structure 20 for the present invention. The first electrode 40 is electrically connected to the first semiconductor epitaxy layer 21, and the position of the first electrode 40 corresponds to the aforementioned first electrode projection area A1. The second electrode 50 is electrically connected to the current conducting layer 24, and the position of the second electrode 50 corresponds to the aforementioned second electrode projection area A2. In one embodiment of the present invention, the first electrode 40 is an N-metal electrode, and the second electrode 50 is a P-metal electrode. Since structural configurations of the first electrode 40 and the second electrode 50 are common designs in conventional flip-chip light-emitting diodes, no further details will be described here.

Accordingly, the flip-chip light-emitting diode 1 of the present invention can be manufactured by applying the manufacturing method of the flip-chip light-emitting diode of the present invention. When power is supplied to the first electrode 40 and the second electrode 50 of the flip-chip light-emitting diode 1 of the present invention, electric current flows through the second electrode 50 along at least one current conducting path P arranged in the current conducting layer 24, then through the light-emitting layer 22 for emitting light, and finally to the first electrode 40. The light emitted by the light-emitting layer 22 is emitted outward from the second substrate 30. Because these current conducting paths P are designed to allow the electric current for flowing through positions which would otherwise be difficult for conducting due to their high impedance values, the electric current is evenly distributed throughout the entire current conducting layer 24, thereby increasing the overall light-emitting area of the flip-chip light-emitting diode 1 of the present invention and thereby reducing the current density thereof. Additionally, the aforementioned design also enhances heat dissipating and electrostatic discharging effects of the flip-chip light-emitting diode 1 of the present invention.

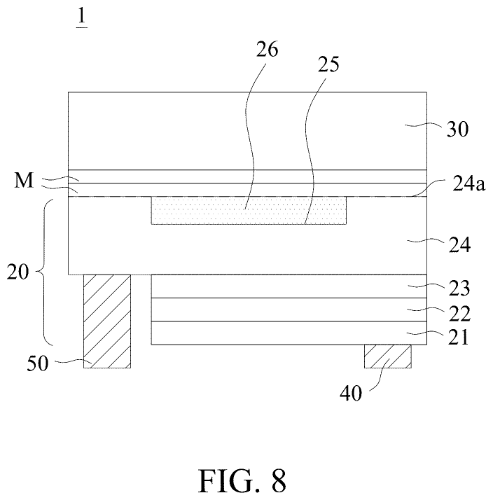

Please refer to FIG. 3 in company with FIG. 8, wherein FIG. 8 is a schematic view of the flip-chip light-emitting diode 1 produced by the manufacturing method of the flip-chip light emitting diode of the present invention. As shown in FIG. 3 and FIG. 8, the present invention also discloses the flip-chip light-emitting diode 1 manufactured by the aforementioned manufacturing method of the flip-chip light emitting diode. In the relative manufacturing processes, the at least one groove 25, filled with the transparent material 26, is formed on the bonding side 24a of the current conducting layer 24 to serve as the current conducting block or the current separating block correspondingly for the flip-chip light-emitting diode 1 of the present invention, thereby modifying the at least one current conducting path P formed on the bonding side 24a. Since the structural components and their functions of the flip-chip light-emitting diode 1 of the present invention have been described in the aforementioned steps, no further details will be given here.

The above implementations are only auxiliary descriptions, and are not intended to limit the embodiments of the application subject or the applications or uses of the embodiments. In addition, although at least one illustrative example has been presented above, it should be understood that the present invention can still have a large quantity of variations. It should also be understood that the embodiments described herein are not intended to limit the scope, use, or configuration of the requested subject matter in any way. On the contrary, the foregoing embodiments will provide a convenient guide for those skilled in the art to implement one or more embodiments. Furthermore, various changes can be made to the function and arrangement of the components without departing from the scope defined by the patent claims, and the scope of the patent claims includes known equivalents and all foreseeable equivalents at the time that the patent application is filed.

1. A manufacturing method of a flip-chip light emitting diode, comprising:
providing a first substrate;
performing an epitaxy process on the first substrate to form a semiconductor structure, wherein the semiconductor structure includes a first semiconductor epitaxy layer, a light-emitting layer, a second semiconductor epitaxy layer and a current conducting layer, in sequence from a position adjacent to the first substrate, and wherein a bonding side is formed for the current conducting layer and a first electrode projection area and a second electrode projection area are defined thereon;
performing an etching process to form at least one groove on the bonding side, wherein each groove extends from a side near the first electrode projection area to a side near the second electrode projection area;
performing a filling process to fill a transparent material into the at least one groove for changing a current conducting path on the bonding side;
performing a bonding process to bond the second substrate to the bonding side; and
removing the first substrate and forming a first electrode and a second electrode on a side of the semiconductor structure adjacent to the first substrate, wherein a position of the first electrode corresponds to the first electrode projection area and the first electrode is electrically connected to the first semiconductor epitaxy layer, and wherein a position of the second electrode corresponds to the second electrode projection area and the second electrode is electrically connected to the current conducting layer.

2. The manufacturing method of the flip-chip light emitting diode as claimed in claim 1, wherein the at least one groove is located at a position other than a position on a shortest connection path between the first electrode projection area and the second electrode projection area.

3. The manufacturing method of the flip-chip light emitting diode as claimed in claim 2, wherein an impedance value of the transparent material is lower than an impedance value of the current conducting layer.

4. The manufacturing method of the flip-chip light emitting diode as claimed in claim 3, wherein the impedance value of the current conducting layer is 10 to 1000 times of the impedance value of the transparent material.

5. The manufacturing method of the flip-chip light emitting diode as claimed in claim 2, wherein the transparent material is selected from one of following material groups of indium zinc oxide, aluminum zinc oxide and indium tin oxide.

6. The manufacturing method of the flip-chip light emitting diode as claimed in claim 1, wherein one of the at least one groove is located at a position on a shortest connection path between the first electrode projection area and the second electrode projection area.

7. The manufacturing method of the flip-chip light emitting diode as claimed in claim 6, wherein an impedance value of the transparent material is higher than an impedance value of the current conducting layer.

8. The manufacturing method of the flip-chip light emitting diode as claimed in claim 7, wherein the impedance value of the transparent material is 10 to 1000 times of the impedance value of the current conducting layer.

9. The manufacturing method of the flip-chip light emitting diode as claimed in claim 6, wherein the transparent material is selected from one of following material groups of silicon oxide, silicon nitride and magnesium fluoride.

10. The manufacturing method of the flip-chip light emitting diode as claimed in claim 1, wherein each at least one groove is a straight-line groove, a rectangular groove, a circular groove, an elliptical groove, a curved groove, a fence-like groove, a tree-like groove or a radial groove.

11. A flip-chip light emitting diode, manufactured according to the manufacturing method of the flip-chip light emitting diode as claimed in claim 1.
